(19) United States
(12) Patent Application Publication
(10) Pub. No.: US 2024/0381624 A1
(43) Pub. Date: Nov. 14, 2024

(54) SEMICONDUCTOR DEVICES AND MANUFACTURING METHODS THEREOF

(71) Applicant: SAMSUNG ELECTRONICS CO., LTD., Suwon-si (KR)

(72) Inventor: Junhyeok AHN, Suwon-si (KR)

(21) Appl. No.: 18/489,472

(22) Filed: Oct. 18, 2023

(30) Foreign Application Priority Data
May 8, 2023 (KR) 10-2023-0059258

(51) Int. Cl. H10B 12/00

(52) U.S. Cl. CPC H10B 12/482; H10B 12/02; H10B 12/315; H10B 12/34; H10B 12/488

(57) ABSTRACT

An embodiment provides a manufacturing method of a semiconductor device, including: forming first and second word lines in a substrate, wherein respective ends of the first and second word lines are connected to each other; forming a first separation groove between the first word line and the second word line, wherein the first separation groove includes a first insulating layer; and forming first and second bit lines on the substrate.

### CROSS-REFERENCE TO RELATED APPLICATION

This application claims priority to and the benefit of Korean Patent Application No. 10-2023-0059258, filed in the Korean Intellectual Property Office on May 8, 2023, the entire contents of which are incorporated herein by reference.

### BACKGROUND

The present disclosure relates to semiconductor devices and manufacturing methods therefor.

As an integration degree of semiconductor devices, e.g., semiconductor memory devices, increases, circuits may become more minute, and accordingly, design rules may be reduced, making processes increasingly complex and difficult. Particularly, the possibility of defects, such as disconnections or short circuits, in signal lines, such as word lines or bit lines, transferring signals may increase.

### SUMMARY

The present disclosure may reduce defects of signal lines and thereby improve the performance of semiconductor devices that include the signal lines.

A manufacturing method for a semiconductor device, comprising: forming first and second word lines in a substrate, wherein respective ends of the first and second word lines are connected to each other; forming a first separation groove between the first word line and the second word line, wherein the first separation groove includes a first insulating layer; and forming first and second bit lines on the substrate.

A manufacturing method for a semiconductor device, comprising: forming first and second word lines in a substrate, wherein respective ends of the first and second word lines are electrically connected to each other; forming a first separation groove, wherein the first word line and the second word line are electrically separated by the first separation groove and the first separation groove is at least filled by a first insulating layer; and forming first and second bit lines on the substrate.

A manufacturing method for a semiconductor device, comprising: forming first and second word lines in a substrate, wherein respective ends of the first and second word lines are electrically connected to each other; forming a first separation groove between the first word line and the second word line, wherein the first separation groove is at least filled by a first insulating layer; forming first and second bit lines on the substrate; forming third and fourth word lines in the substrate separated from the first and second word lines, and electrically connected to each other at respective ends; and forming a second separation groove between the third word line and the fourth word line.

As such, disconnections and short circuits of word lines may be reduced.

### BRIEF DESCRIPTION OF THE DRAWINGS

FIG. 1 illustrates a schematic layout view of a semiconductor device according to some embodiments of the present disclosure.

FIG. 2 illustrates a cross-sectional view of the semiconductor device of FIG. 1 taken along a line II-II′ according to some embodiments of the present disclosure.

FIG. 3 illustrates a cross-sectional view of the semiconductor device of FIG. 1 taken along a line III-III′ according to some embodiments of the present disclosure.

FIG. 4 illustrates a schematic layout view in an intermediate process of manufacturing a semiconductor device according to some embodiments of the present disclosure.

FIG. 5 and FIG. 6 each illustrate a cross-sectional view of the semiconductor device of FIG. 4 taken along a line V-V′ according to a process order.

FIG. 7 illustrates a schematic layout view in an intermediate process of manufacturing a semiconductor device according to some embodiments of the present disclosure.

FIG. 8 and FIG. 9 each illustrate a cross-sectional view of the semiconductor device of FIG. 7 taken along a line VIII-VIII′ according to a process order.

FIG. 10 illustrates a schematic layout view in an intermediate process of manufacturing a semiconductor device according to some embodiments of the present disclosure.

FIG. 11 and FIG. 12 each illustrate a cross-sectional view of the semiconductor device of FIG. 10 taken along a line XI-XI′ according to a process order.

FIG. 13 illustrates a schematic layout view in an intermediate process of manufacturing a semiconductor device according to some embodiments of the present disclosure.

FIG. 14 and FIG. 15 each illustrate a cross-sectional view of the semiconductor device of FIG. 13 taken along a line XIV-XIV′ according to a process order.

FIG. 16 to FIG. 21 each illustrate a layout diagram of a word line separation groove and a word line connection plug of a semiconductor device according to some embodiments of the present disclosure.

### DETAILED DESCRIPTION

In the following detailed description, only some embodiments of the present disclosure are shown and described, simply by way of illustration. As those skilled in the art would realize, the described embodiments may be modified in various different ways, all without departing from the scope of the present invention. Accordingly, the drawings and description are to be regarded as illustrative in nature and not restrictive. Like reference numerals designate like elements throughout the specification.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. It will be understood that “connection” may include a physical connection and an electrical connection. In addition, it will also be understood that when an element or layer is referred to as being “between” two elements or layers, it may be the only element or layer between the two elements or layers, or one or more intervening elements or layers may also be present.

Spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

The accompanying drawings may relate to dynamic random access memory (DRAM), but the present disclosure is not limited thereto.

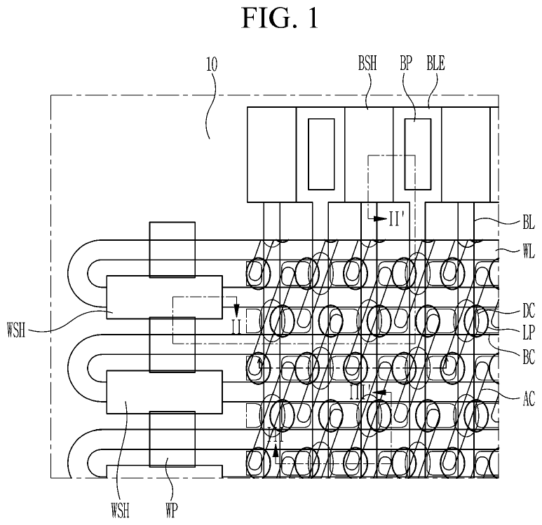

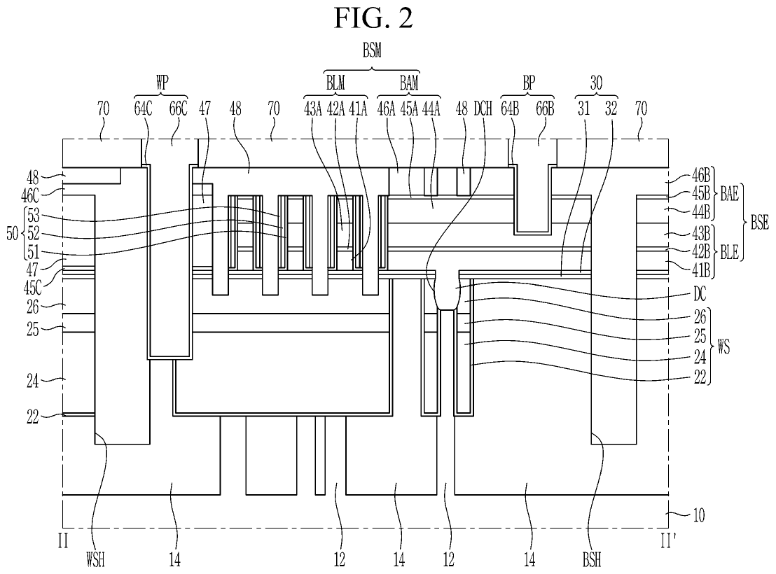

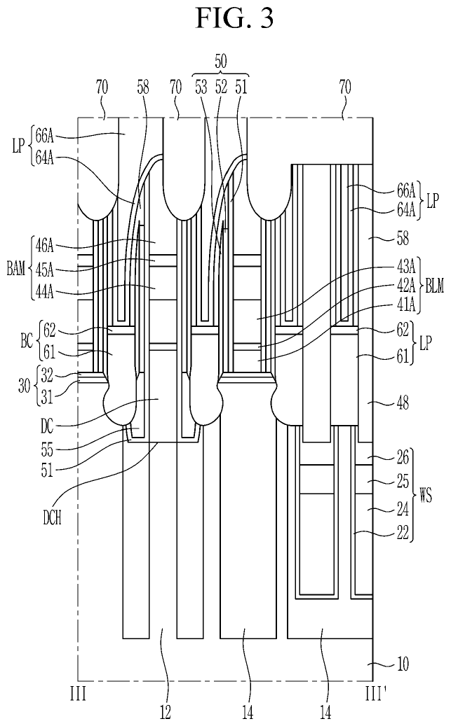

FIG. 1 illustrates a schematic layout view of a semiconductor device according to some embodiments of the present disclosure, FIG. 2 illustrates a cross-sectional view of the semiconductor device of FIG. 1 taken along a line II-II′ according to some embodiments of the present disclosure, and FIG. 3 illustrates a cross-sectional view of the semiconductor device of FIG. 1 taken along a line III-III′ according to some embodiments of the present disclosure.

Referring to FIG. 1, a semiconductor device according to some embodiments of the present disclosure may include a substrate 10, and may include a plurality of word lines WL (or a word line WL), a plurality of bit lines BL (or a bit line BL), and a plurality of active areas AC (an active area AC) inside or outside the substrate 10.

The word lines WL may extend in a first horizontal direction, e.g., parallel to each other. The word lines WL may be arranged at equal intervals. A width of the word line WL or a distance between the word lines WL may be determined according to a design rule. The first horizontal direction may be parallel with an upper surface of the substrate 10.

The bit lines BL may overlap (e.g., cross) the word lines WL. The bit lines BL may extend in a second horizontal direction. The second horizontal direction may be perpendicular to the first horizontal direction. The first and second horizontal directions may be referred to as (a) horizontal direction(s). The second horizontal direction may be parallel with the upper surface of the substrate 10. The bit lines BL may be arranged parallel to each other. The bit lines BL may be arranged at equal intervals. As used herein, “an element A overlapping an element B in a direction X” (or similar language) means that there is at least one line that extends in the direction X and intersects both the elements A and B.

The word lines WL and the bit lines BL may be electrically insulated from each other. For example, the word line WL and the bit line BL may overlap (e.g., cross) each other with an insulating layer interposed therebetween, and the bit line BL may be positioned above the word line WL at an intersection. The bit line BL may be farther than the word line WL from the upper surface of the substrate 10 in a vertical direction perpendicular to the upper surface of the substrate 10. However, the relative vertical locations of the word line WL and the bit line BL are not limited thereto.

The word line WL and the bit line BL may overlap (e.g., cross) each other to define a cell (e.g., cell area). An end portion of the word line WL may be connected to a word line connection plug WP, and an end portion of the bit line BL may be connected to a bit line connection plug BP for electrical connection to the outside. The word line WL and the bit line BL may be referred to as (a) signal line(s) WL and/or BL. The word line connection plug WP and the bit line connection plug BP may be referred to as (a) connection plug(s) WP and/or BP. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device. The connection plugs WP and BP may be alternately (e.g., intermittently) positioned to prevent a short circuit between the connection plugs WP and BP. For example, FIG. 1 illustrates only the word line connection plugs WP connected to the odd-numbered word lines WL, but a word line connection plug WP connected to the even-numbered word line WL may be positioned at an opposite side, that is, at a right end portion in FIG. 1, but for better understanding and ease of description, the illustration is omitted. Similarly, FIG. 1 illustrates only the bit line connection plugs BP connected to the even-numbered bit lines BL, but a bit line connection plug BP connected to the odd-numbered bit line BL may be positioned at an opposite side, that is, at a lower end portion in FIG. 1, but for better understanding and ease of description, the illustration is omitted.

In addition, a word line separation groove WSH and a bit line separation groove (e.g., referred to as (a) separation groove(s) WSH and/or BSH) filled with an insulator may be positioned between the connection plugs WP and BP and between the signal lines WL and BL in order to prevent a short circuit between the connection plugs WP and BP or between the signal lines WL and BL. For example, the word line separation groove WSH may be between the word lines WL and/or the word line connection plugs WP. The bit line separation groove BSH may be between the bit lines BL and/or the bit line connection plugs BP. Each of the separation grooves WSH and BSH may be positioned on an extension line near an end portion of one of the signal lines WL and BL. Each of the separation grooves WSH and BSH may be larger (e.g., wider, deeper, and/or taller) than the signal lines WL and BL (in the first horizontal direction, the second horizontal direction, and/or the vertical direction), and thus the corresponding one of the signal lines WL and BL may be cut (e.g., disconnected) by the separation grooves WSH and BSH, respectively, near the end portion of the corresponding one of the signal lines WL and BL.

Positions of odd-numbered and even-numbered signal lines WL and BL may be reversed. For example, the inventive concepts of the present disclosure are not limited to the relative locations of the odd-numbered and even-numbered signal lines WL and BL.

The shapes and relative positions of the connection plugs WP and BP and the separation grooves WSH and BSH according to some embodiments of the present disclosure are not limited thereto.

An end portion of the bit line BL connected to the bit line connection plug BP may be expanded to have a large area (e.g., wider width than a remaining portion of the bit line BL other than the end portion of the bit line BL in the first horizontal direction). Hereinafter, the large area at the end portion of the bit line BL may be referred to as a bit line extension (BLE) and the other portion may be referred to as a bit line main body (BLM).

Widths of the word lines WL and the bit lines BL, a distance between the word lines WL, a distance between the bit lines BL, and the like may be determined according to a design rule.

Each of the active areas AC (or an active area AC) may overlap (e.g., cross) the word line WL with an insulating layer provided therebetween and may be connected to the bit line BL. Each of the active areas AC (or the active area AC) may also be connected to a capacitor (not illustrated). Through such a structure, a transistor having a channel in the active area AC may be formed, and in this case, the word line WL may serve as a gate electrode, and portions positioned at opposite sides of the word line WL in the active area AC may function as a source region and a drain region.

According to some embodiments, the active area AC may be an elongated shape (e.g., a long island shape) having a shorter axis and a longer axis, and, for example, as illustrated in FIG. 1, it may have a long bar shape in a diagonal line direction or oblique line direction. The diagonal line direction may intersect with the first and second horizontal directions. The diagonal line direction may be parallel with the upper surface of the substrate 10. This shape may be due to reduction of the design rules of the semiconductor device, the shape of the active area AC according to some embodiments of the present disclosure is not limited thereto.

According to some embodiments of the present disclosure, each active area AC may overlap (e.g., cross) two word lines WL (e.g., in the vertical direction) and be connected to one bit line BL. In this case, the active area AC may be divided into three portions with the word lines WL as boundaries in a plan view (referring to FIG. 1). The three portions of the active area AC may include an intermediate portion connected to the bit line BL through a direct contact DC and opposite ends connected to a capacitor (not illustrated) through a buried contact BC and/or a landing pad LP.

The direct contact DC may overlap (e.g., in the vertical direction) and contact the bit line BL and the active area AC, and may be positioned at a center portion (e.g., the intermediate portion) of the active area AC in a plan view (referring to FIG. 1). The buried contact BC may overlap (e.g., in the vertical direction) and contact opposite end portions of the active area AC in a plan view (referring to FIG. 1) and may be positioned within a space partitioned by a partition wall 48 extending in the first horizontal direction and the bit line BL extending in the second horizontal direction. The partition wall 48 may be completely overlapped by the word line WL (e.g., in the vertical direction), and may be narrower (e.g., may include a narrower width in the first horizontal direction) than the word line WL.

The landing pad LP may overlap (e.g., in the vertical direction) and contact the buried contact BC, and may be positioned in a space between adjacent word lines WL. However, the positions of the landing pad LP are not limited thereto. The landing pad LP may also contact one electrode of a capacitor (not illustrated). The landing pad LP, which is introduced in consideration of a narrow area of the buried contact BC due to a layout structure, may reduce contact resistance by increasing an actual contact area between the buried contact BC and the electrode of the capacitor. However, the embodiment of the present disclosure is not limited thereto, and the landing pad LP may be omitted.

According to some embodiments of the present disclosure, direct contacts DC of the odd-numbered bit lines BL and direct contacts DC of the even-numbered bit lines BL may be staggered with each other (e.g., in the second horizontal direction), and positions of the landing pads LP may also be staggered each other (e.g., in the second horizontal direction). For example, a direct contact DC of an odd-numbered bit line BL and another direct contact DC of an even-numbered bit line BL that is adjacent to the odd-numbered bit line BL may have different relative location in the second horizontal direction. In this way, a small area of the semiconductor device may be efficiently utilized.

However, the embodiments of the present disclosure are not limited thereto, and the direct contacts DC may be disposed in various ways.

The word line WL, the bit line BL, the active area AC, the direct contact DC, the buried contact BC, the landing pad LP, etc. may be implemented (e.g., disposed) on the substrate 10 in various embodiments.

Referring to FIG. 2 and FIG. 3, a semiconductor device according to some embodiments of the present disclosure may include the substrate 10. The substrate 10 may be a silicon substrate or a silicon-on-insulator (SOI). In some embodiments, the substrate 10 may include silicon germanium, silicon germanium on insulator (SGOI), indium antimonide, lead tellurium compound, indium arsenide, indium phosphide, gallium arsenide, or gallium antimonide, but the present disclosure is not limited thereto.

The active area AC may be defined by a region separation layer 14 formed in the substrate 10. That is, a portion of the substrate 10 without the region separation layer 14 may be an active area 12. The active area 12 corresponds to a reference numeral AC in FIG. 1 (the active area AC).

The region separation layer 14 may occupy a predetermined depth from a surface (e.g., the upper surface) of the substrate 10. For example, the region separation layer 14 may have a shallow trench isolation (STI) structure in which a trench is formed (e.g., extend) to a predetermined depth from the surface (e.g., the upper surface) of the substrate 10 (e.g., in the vertical direction). The region separation layer 14 may include an insulating material. For example, the trench may include an insulating material. The trench may at least partially be filled with the insulating material.

FIG. 2 and FIG. 3 illustrate that an upper surface of the region separation layer 14 is positioned on a same plane as the upper surface of the substrate 10, but this is only for convenience of description and is not limited thereto.

The region separation layer 14 may include a silicon oxide (SiOₓ), a silicon nitride (SiNₓ), a silicon oxynitride (SiON), or a combination thereof, but the present disclosure is not limited thereto. Although the region separation layer 14 is illustrated as a single layer in FIG. 3, it is only for convenience of description, and the present disclosure is not limited thereto. Each of the region separation layers 14 may be formed as one insulating layer or a plurality of insulating layers depending on a width thereof.

The word line WL according to some embodiments of the present disclosure may be a buried type. In FIG. 3, a word line structure WS formed in the substrate 10 may be related to (e.g., may include) the word line WL. The word line structure WS may extend into (e.g., cross) the region separation layer 14 and the active area 12. The word line structure WS may include a word line 24 (corresponding to the word line WL), and a capping conductive layer 25 and a capping insulating layer 26 sequentially positioned (e.g., stacked) on the word line 24, and a gate insulating layer 22 extending around (e.g., surrounding) lower and side surfaces of the word line 24, a side surface of the capping conductive layer 25, and/or a side surface of the capping insulating layer 26.

The word line structure WS may be formed in a trench that is formed in the substrate 10. The trench may be formed by an etching process.

Referring to FIG. 2 and FIG. 3, the gate insulating layer 22 may be disposed (e.g., thinly coated) on a surface (e.g., an inner surface) of the trench and formed along a curved surface of the trench. However, the embodiment of the present disclosure is not limited thereto.

The gate insulating layer 22 may include, for example, silicon oxide, silicon nitride, silicon oxynitride, or a high-k material having a higher dielectric constant than that of silicon oxide. For example, the high-k material may include hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and/or a combination thereof.

The word line 24 may be positioned on the gate insulating layer 22. The word line 24 may, at least partially, fill a lower portion of the trench. The word line 24 may be formed as a single layer or multiple layers.

For example, each of the word line 24 and the capping conductive layer 25 may include, for example, a metal, a metal alloy, a conductive metal nitride, a conductive metal carbonitride, a conductive metal carbide, a metal silicide, a semiconductor material containing impurities, a conductive metal oxynitride, and/or a conductive metal oxide. For example, the word line 24 may include TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MON, MOC, WC, Rh, Pd, Ir, Ag, Au, Zn, V, RuTiN, TiSi, TaSi, NiSi, CoSi, IrOx, RuOx, and/or a combination thereof.

The capping insulating layer 26 may, at least partially, fill an upper portion of the trench. FIG. 2 and FIG. 3 illustrate that the gate insulating layer 22 is disposed on (e.g., covers) an entire sidewall of the trench. In some embodiments, however, the gate insulating layer 22 may be disposed on (e.g., cover or overlap) only a lower portion of the sidewall of the trench, and an upper portion of the sidewall of the trench may contact the capping insulating layer 26 without the gate insulating layer 22 therebetween.

For example, the capping insulating layer 26 may include silicon nitride (SiN), silicon oxynitride (SiON), silicon oxide (SiO₂), silicon carbonitride (SiCN), silicon oxycarbonitride (SiOCN), and/or a combination thereof.

At least a portion of the word line structure WS may overlap the active area 12 (e.g., in the vertical direction).

A buffer layer 30 may be formed on a surface (e.g., the upper surface) of the substrate 10 that includes the active area 12, the region separation layer 14 and the word line structure WS. The buffer layer 30 may have various contact holes exposing the surface (e.g., the upper surface) or an inside of the substrate 10 along with other insulating structures.

As illustrated in FIG. 2 and FIG. 3, the buffer layer 30 may be a multilayer including a lower insulating layer 31 and an upper insulating layer 32 on the lower insulating layer 31. For example, the lower insulating layer 31 may include silicon oxide, and the upper insulating layer 32 may include a metal oxide and/or silicon nitride, but the present disclosure is not limited thereto. Unlike the illustration, the buffer layer 30 may be a triple layer including a silicon oxide layer, a metal oxide layer, and a silicon nitride layer, but the present disclosure is not limited thereto, and the buffer layer 30 may be formed as a single insulating layer or four or more insulating layers.

The bit line BL according to some embodiments of the present disclosure may be a stacked type that is formed by stacking layers on the substrate 10, and as illustrated in FIG. 2 and FIG. 3, may include the bit line main body (BLM) and the bit line extension (BLE) connected thereto.

In some embodiments of the present disclosure, the bit line BL may include multiple layers. For example, the bit line BL may include first and second lower conductive layers 41A and 41B (referred to as (a) lower conductive layer(s) 41, 41A and/or 41B), first and second intermediate conductive layers 42A and 42B (referred to as (an) intermediate conductive layer(s) 42, 42A and/or 42B), and first and second upper conductive layers 43A and 43B (referred to as (an) upper conductive layer(s) 43, 43A and/or 43B). The first lower conductive layer 41A, the first intermediate conductive layer 42A, and the first upper conductive layer 43A may be sequentially stacked. The second lower conductive layer 41B, the second intermediate conductive layer 42B, and the second upper conductive layer 43B may be sequentially stacked. However, the embodiment of the bit line BL is not limited thereto, and may include, e.g., a single conductive layer, a double (dual) conductive layer, or four or more conductive layers.

The first and second lower conductive layers 41A and 41B, the first and second intermediate conductive layers 42A and 42B, and the first and second upper conductive layers 43A and 43B may each include, for example, a semiconductor material containing impurities, a conductive silicide compound, a conductive metal nitride, a metal, and/or a metal alloy. For example, the first and second lower conductive layers 41A and 41B may each include an impurity-containing semiconductor material (e.g., polysilicon, etc.), the first and second intermediate conductive layers 42A and 42B may each include, for example, a conductive silicide compound and/or a conductive metal nitride, and the first and second upper conductive layers 43A and 43B may each include, for example, a metal and/or a metal alloy, but the present disclosure is not limited thereto.

The bit line BL may be directly connected to the active area 12 through the direct contact DC.

The direct contact DC may be formed in a direct contact hole DCH formed in the buffer layer 30 and the active area 12, an upper surface thereof may contact the bit line BL, and a lower surface thereof may contact the active area 12. The direct contact DC may be formed of a same material as that of a lower surface of the bit line BL in order to reduce contact resistance with the bit line BL.

When the bit line BL is a multilayer, a layer positioned at a lower portion (e.g., the lowermost portion) may be connected to the active area 12 through the direct contact DC. In some embodiments, for example, referring to FIG. 3, the direct contact DC may be a portion of the first lower conductive layer 41A positioned at the lower portion (e.g., the lowermost portion) of the bit line BL, particularly the bit line body BLM.

The direct contact DC may not contact a sidewall of the direct contact hole DCH, there may be a space between the sidewall of the direct contact DC and the sidewall of the direct contact hole DCH, and this space may, at least partially, be filled with an insulating spacer or a insulating material. For example, referring to FIG. 3, an inner spacer 51 and a filling spacer 55 may be filled in the space between the sidewall of the direct contact hole DCH and the sidewall of the direct contact DC. The inner spacer 51 may disposed on (e.g., cover or overlap) the sidewall and lower surface of the direct contact hole DCH and the side surface of the direct contact DC, and may be formed along a curved surface of those surfaces. The filling spacer 55 may fill a remaining empty space of the contact hole DCH. However, the embodiment of the present disclosure is not limited thereto, and other filling spacers may be further included, for example.

A bit line capping may be on (e.g., at least partially cover or overlap) an upper surface of the bit line BL. The bit line capping may include a capping body BAM positioned on the bit line body BLM and a capping extension BAE positioned on the bit line extension BLE. Hereinafter, for convenience, the capping body BAM and the capping extension BAE may be collectively referred to as “bit line capping BA”. The bit line capping BA may reduce damage to the bit line BL in a process after forming the bit line BL. The bit line capping BA may include, for example, silicon nitride, silicon oxynitride, silicon carbonitride, and/or silicon oxycarbonitride.

As illustrated in FIG. 2 and FIG. 3, the bit line capping BA may have a triple layer structure. For example, the bit line capping BA may include first and second insulating capping layers 44A and 44B (collectively referred to as insulating capping layer 44), first and second intermediate insulating layers 45A and 45B (collectively referred to as intermediate insulating layer 45), and first and second mask layers 46A and 46B (collectively referred to as mask layer 46). The first and second insulating capping layers 44A and 44B, the first and second intermediate insulating layers 45A and 45B, and the first and second mask layers 46A and 46B may each include, for example, silicon nitride, silicon oxynitride, silicon carbonitride, or silicon oxycarbonitride.

FIG. 3 illustrates that the bit line capping BA is a triple layer, but the present disclosure is not limited thereto. Unlike the illustration, the bit line capping BA may have a structure of a single layer, a double (dual) layer, or a quadruple layer or more.

The bit line BL and the bit line capping BA may have substantially a same shape in a plan view, and may be formed using a same mask.

In this specification, hereinafter, the bit line BL and the bit line capping BA may be collectively referred to as “bit line structure BS”, the bit line body BLM and the capping body BAM may be collectively referred to as “bit line structure body BSM”, and the bit line extension BLE and the capping extension BAE may be collectively referred to as “bit line structure extension BSE”.

A bit line separation groove BSH may be positioned between the bit line structure extensions BSE, a sidewall of the bit line separation groove BSH may comprise the second intermediate insulating layer 45B, the second insulating capping layer 44B, the second lower conductive layer 41B, the second intermediate conductive layer 42B, the second upper conductive layer 43B, the buffer layer 30, and/or the substrate 10, and an inside thereof may be filled with the second mask layer 46B. For example, the bit line separation groove BSH may extend in the second intermediate insulating layer 45B, the second insulating capping layer 44B, the second lower conductive layer 41B, the second intermediate conductive layer 42B, the second upper conductive layer 43B, the buffer layer 30, and/or the substrate 10 in the vertical direction. The bit line separation groove BSH may be positioned at the opposite side of the extension BSE, that is, on an extension of the bit line structure BS positioned downward in FIG. 1, and an end of the bit line structure BS may form a portion of a sidewall of the bit line separation groove BSH.

Bit line spacers 50 (in FIG. 2 and FIG. 3) may be formed on opposite side surfaces of the bit line structure BS. According to some embodiments of the present disclosure, for example, referring to FIG. 2, the bit line spacers 50 may extend vertically along the bit line BL (or bit line structure BS). The bit line spacers 50 may each include, for example, silicon oxide, silicon nitride, silicon oxynitride (SiON), silicon oxycarbonitride (SiOCN), air, or combination thereof, but the present disclosure is not limited thereto.

The bit line spacer 50 according to some embodiments of the present disclosure may include a plurality of layers. For example, referring to FIG. 2 and FIG. 3, the bit line spacer 50 may include an inner spacer 51, an intermediate spacer 52, and an outer spacer 53 sequentially arranged in order close to the bit line structure BS. For example, the inner spacer 51, the intermediate spacer 52, and the outer spacer 53 may be sequentially stacked on the bit line structure BS. Among them, the inner spacer 51 may contact the bit line structure BS and, as described above, extend along the direct contact DC to be on (e.g., cover) a sidewall and a lower surface of the direct contact hole DCH. The inventive concept of the present disclosure is not limited to the number layers or shape of the bit line spacer 50.

Referring to FIG. 1 to FIG. 3, at an end portion of the word line structure WS, an insulating layer 45C may be disposed on the buffer layer 30, and a filling insulating layer 47 and a mask layer 46C may be disposed on the insulating layer 45C.

The insulating layer 45C and the intermediate insulating layer 45 of the bit line structure BS may be a unitary structure, and the mask layer 46C and the mask layer 46 of the bit line structure BS may be a unitary structure. A unitary structure herein may refer to a structure without a visible boundary between two sub-elements thereof. A unitary structure may be formed by a same process or a series of same processes.

The filling insulating layer 47 may be formed of an insulating material having a desired (e.g., an excellent) charging characteristic. For example, the filling insulating layer 47 may include a boron-phosphor silicate glass (BPSG) film, a high density plasma (HDP) oxide film, an O₃-TEOS film, an undoped silicate glass (USG), and/or a tonen silazene (TOSZ) material.

The word line separation grooves WSH may be positioned on the extension lines of the word line structures WS, and one word line separation groove WSH may be positioned for every two word line structures WS. Lower surfaces of the word line separation grooves WSH may be lower than lower surfaces of the word line structures WS, and a width of the word line separation grooves WSH (e.g., in the second horizontal direction) may be greater than that of the word line structures WS. For example, the lower surfaces of the word line separation grooves WSH may be closer than the lower surfaces of the word line structures WS to a lower surface of the substrate 10 in the vertical direction. The word line separation grooves WSH may be filled with an insulating material. In the embodiment illustrated in FIG. 2, the word line separation groove WSH may extend in the filling insulating layer 47, the insulating layer 45C, and the substrate 10. For example, a sidewall of the word line separation groove WSH may comprise sidewalls of the filling insulating layer 47, the insulating layer 45C, (the buffer layer 30), and the substrate. In some embodiments, the mask layer 46C may at least partially fill the word line separation groove WSH, however, the embodiment of the present disclosure is not limited thereto. In FIG. 2, the lower surfaces of the word line separation grooves WSH are illustrated as being at almost a same level in the vertical direction as lower surfaces of the bit line separation grooves BSH, but the lower surfaces of the word line separation grooves WSH may be positioned higher or lower than the bottom surfaces of the bit line separation grooves BSH in the vertical direction. A pair of word line structures WS connected to each other at an end portion of the pair of word line structures WS may be separated by the word line separation groove WSH. The word line separation groove WSH may overlap at least a portion of one of the word line structures WS of the pair of word line structures WS in the vertical direction. Referring to FIG. 1, the word line separation grooves WSH are formed in even-numbered word line structures WS, but conversely, the word line separation grooves WSH may be formed in odd-numbered word line structures WS.

Referring to FIG. 1 to FIG. 3, the partition wall 48 may extend in a horizontal direction (e.g., the first horizontal direction) to overlap (e.g., cross) the bit line structure body BSM and the bit line spacer 50 (e.g., in the vertical direction). The partition wall 48 may also be completely overlapped by the word line structure WS (e.g., in the vertical direction), and may be narrower (e.g., may include a narrower width in the first horizontal direction) than the word line structure WS. That is, upper and lower boundaries of the partition wall 48 may overlap an inside of the word line structure WS (e.g., in the vertical direction).

A portion of the partition wall 48 positioned in the space between the bit line spacers 50 may extend into the substrate 10, e.g., into the capping insulating layer 26. At a portion where the partition wall 48 and the bit line structure body BSM overlap (e.g., in the vertical direction), the partition wall 48 may be positioned above (e.g., on an upper surface) the bit line structure body BSM, and a height of the bit line structure body BSM may be relatively low. FIG. 2 illustrates a case in which the mask layer 46A is not present in the portion of the capping body BAM positioned below the partition wall 48 and an upper portion of the intermediate insulating layer 45A is also removed. However, the embodiment of the present disclosure is not limited thereto. An upper surface of the partition wall 48 may be lower than an upper surface of a highest portion of the bit line structure body BSM, but the present disclosure is not limited thereto. The partition wall 48 may include, for example, silicon oxide, silicon nitride, silicon oxynitride, and a combination thereof, but the present disclosure is not limited thereto.

The buried contact BC may be positioned in a space partitioned by the partition wall 48 and the bit line spacer 50 and may overlap an end portion of the active area 12. At least a portion of the buried contact BC may be disposed (e.g., buried) in the substrate 10. For example, a lower surface of the buried contact BC may be lower than the upper surface of the substrate 10 and higher than the lower surface of the partition wall 48. An upper surface of the buried contact BC may be lower than the upper surface of the partition wall 48 and higher than the upper surface of the substrate 10, for example, but the present disclosure is not limited thereto.

According to some embodiments of the present disclosure, the buried contact BC may include a lower layer 61 and an upper layer 62. For example, the lower layer 61 may include a semiconductor material containing impurities, a conductive silicide compound, a conductive metal nitride, and/or a metal. The lower layer 61 may include, for example, impurity-containing polysilicon, and the impurity may include, for example, phosphorus, arsenic, boron, and/or a combination thereof. The upper layer 62 may include a metal silicide.

A cell spacer 58 may be formed on side surfaces of the bit line spacer 50 and the partition wall 48 defining the buried contact BC. The cell spacer 58 may extend to an upper surface of the buried contact BC.

The landing pad LP may be formed on the buried contact BC to be connected to the buried contact BC. The landing pad LP may overlap a portion of the upper surface of the bit line structure body BSM (e.g., in the vertical direction).

The word line connection plug WP and the bit line connection plug BP may overlap the word line WL and the bit line BL, respectively. As illustrated in FIG. 1, the word line connection plug WP may be wider (e.g., in the second horizontal direction) than the word line WL, but is not limited thereto. The word line connection plug WP may extend to the word line 24 through the partition wall 48, the mask layer 46C, the buried insulating layer 47, the insulating layer 45C, (the buffer layer 30), the capping insulating layer 26, and the capping conductive layer 25. The bit line connection plug BP may be smaller than the bit line structure extension BSE, and may be positioned at a center portion of the bit line structure extension BSE in a plan view. The bit line connection plug BP may extend through the capping extension BAE to contact the upper conductive layer 43B of the bit line extension BLE.

Referring to FIG. 2 and FIG. 3, the landing pad LP may include a first conductive barrier layer 64A, the bit line connection plug BP may include a second conductive barrier layer 64B, and the word line connection plug WP may include a third conductive barrier layer 64C. The first, second, and the third conductive barrier layers 64A, 64B, and 64C may be collectively referred to as conductive barrier layers 64A, 64B, and 64C. First, second, and third conductive layers 66A, 66B, and 66C may be sequentially stacked on the first, second, and third conductive barrier layers 64A, 64B, and 64C, respectively. The first, second, and third conductive layers 66A, 66B, and 66C may be collectively referred to as conductive layers 66A, 66B, and 66C. The conductive barrier layers 64A, 64B, and 64C may have a stacking structure of Ti, TiN or Ti/TIN, for example. The conductive layers 66A, 66B, and 66C may include, for example, a semiconductor material containing impurities, a conductive silicide compound, a conductive metal nitride, a conductive metal carbide, a metal, and/or a metal alloy.

A pad separation insulating layer 70 may separate the landing pad LP and the connection plugs WP and BP, and may erode the bit line structure BS, the bit line spacer 50 and the cell spacer 58. For example, the pad separation insulating layer 70 may be between the landing pad LP and the connection plugs WP and BP. The pad separation insulating layer 70 may extend in the bit line structure BS, the bit line spacer 50 and the cell spacer 58.

The pad separation insulating layer 70 may include an insulating material and may electrically separate the landing pads LP from each other. For example, the pad separation insulating layer 70 may include silicon oxide, silicon nitride, silicon oxynitride, silicon oxycarbonitride, and/or silicon carbonitride.

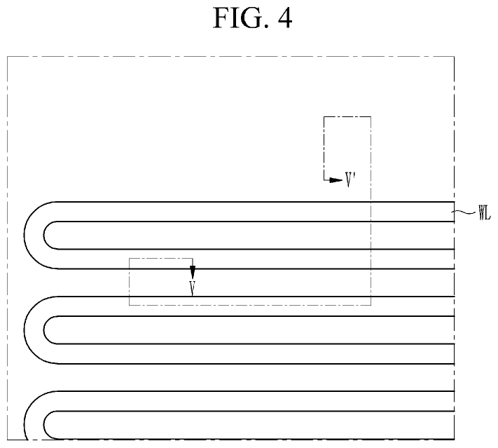

Next, a method of manufacturing the semiconductor device shown in FIG. 1 to FIG. 3 according to some embodiments of the present disclosure will be described in detail with reference to FIG. 4 to FIG. 15.

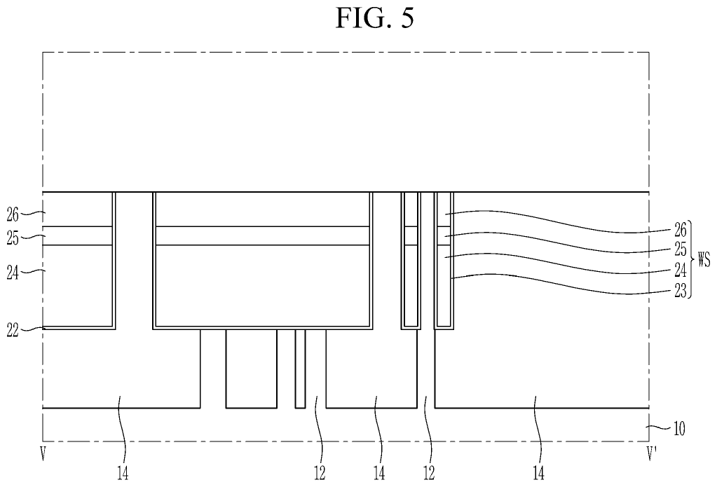

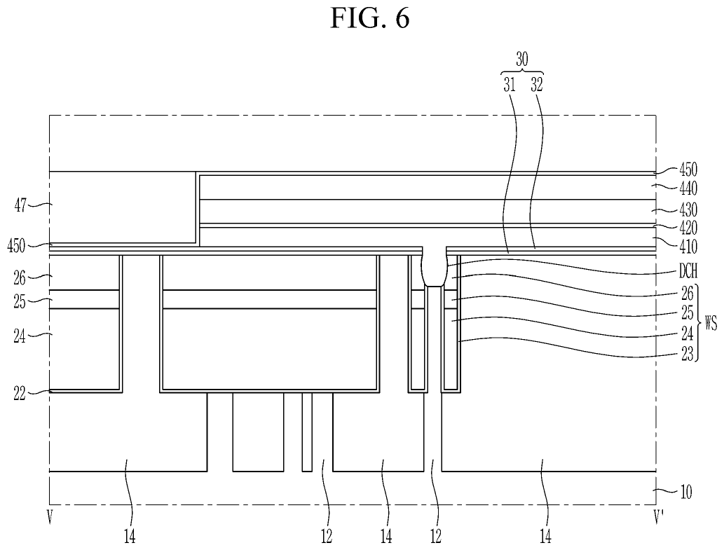

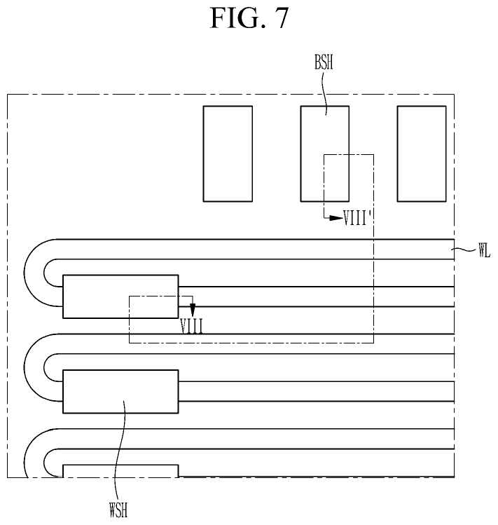

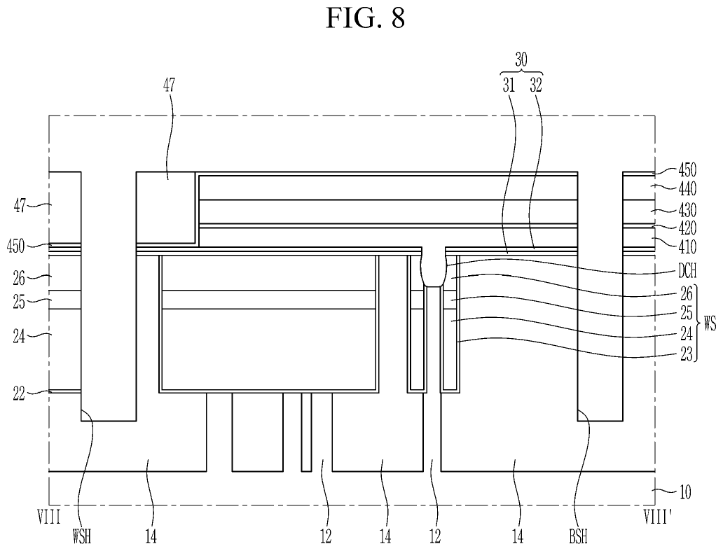

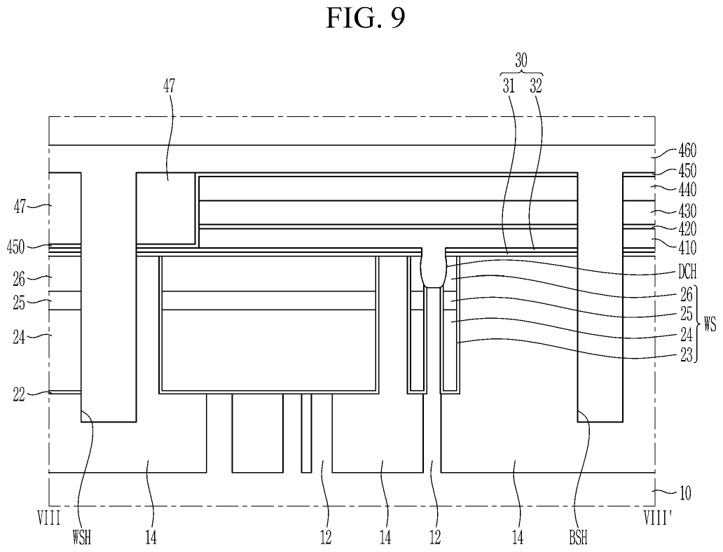

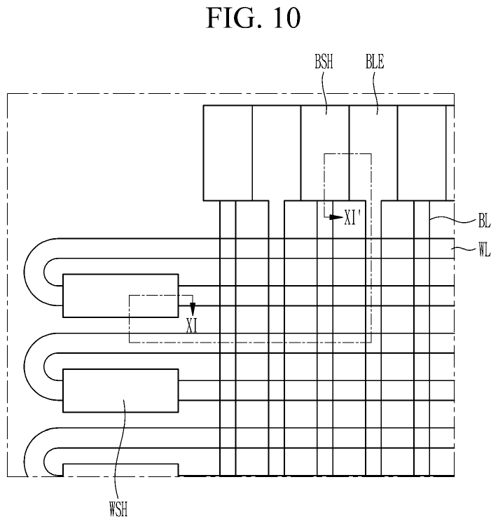

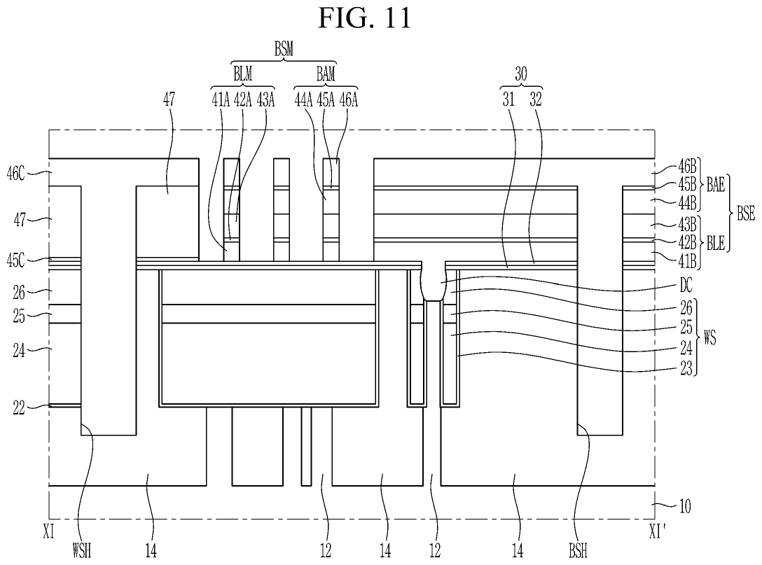

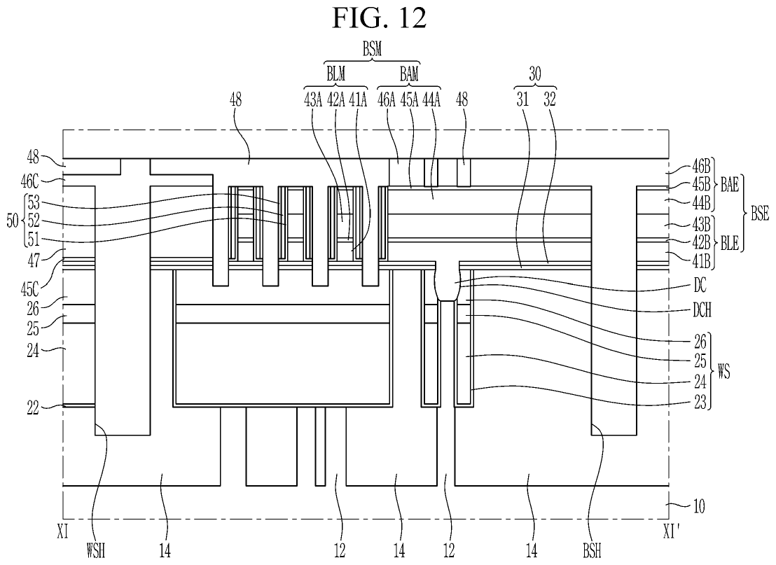

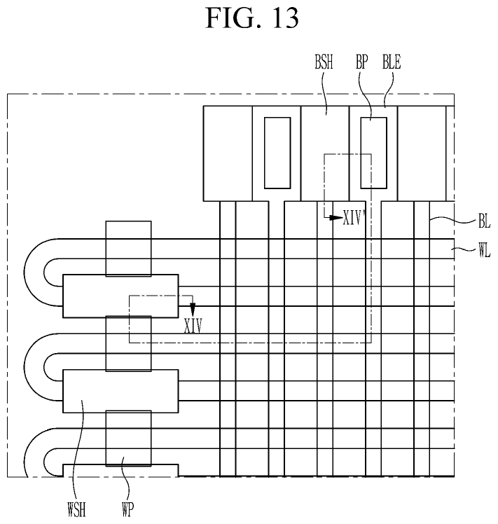

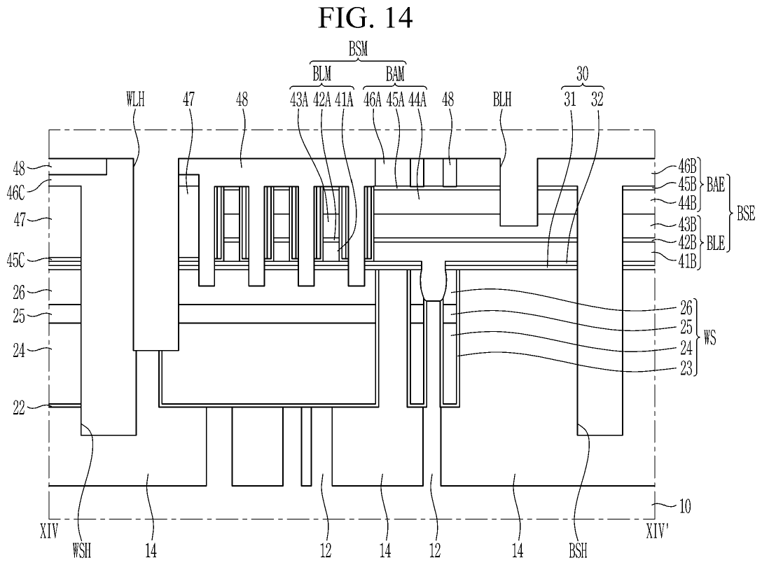

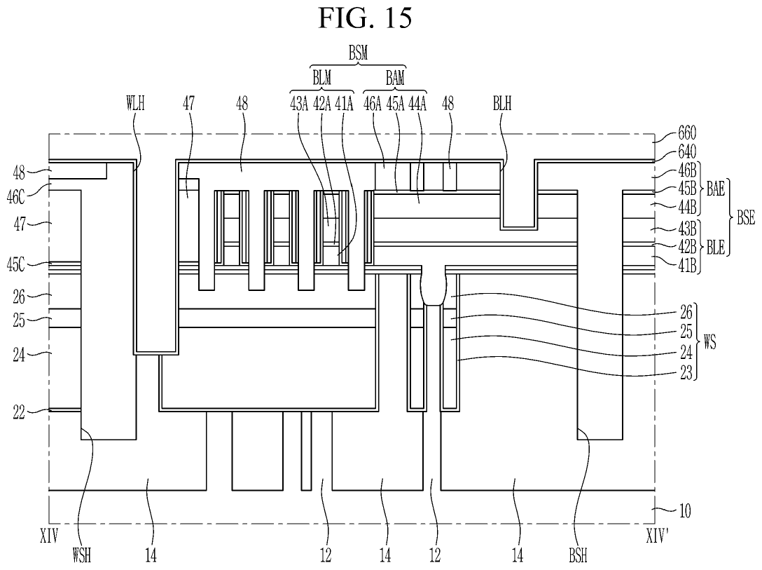

FIG. 4, FIG. 7, FIG. 10, and FIG. 13 each illustrate a schematic layout view in an intermediate process of manufacturing a semiconductor device according to some embodiments of the present disclosure. FIG. 5 and FIG. 6 each illustrate a cross-sectional view of the semiconductor device of FIG. 4 taken along a line V-V″ according to a process order, FIG. 8 and FIG. 9 each illustrate a cross-sectional view of the semiconductor device of FIG. 7 taken along a line VIII-VIII′ according to a process order, FIG. 11 and FIG. 12 each illustrate a cross-sectional view of the semiconductor device of FIG. 10 taken along a line XI-XI′ according to a process order, and FIG. 14 and FIG. 15 each illustrate a cross-sectional view of the semiconductor device of FIG. 13 taken along a line XIV-XIV′ according to a process order.

Referring to FIG. 4 and FIG. 5, the word line structures WS may be formed on the substrate 10 in which the region separation layers 14 defining the active area 12 are formed. The word line structures WS may extend in the horizontal direction (e.g., the first horizontal direction), and are connected to each other at ends thereof in pairs.

According to some embodiments of the present disclosure, after forming the word line structure WS, impurities may be implanted into the active area 12 to form source and drain regions. According to some embodiments of the present disclosure, an impurity ion implantation process for forming the source and drain regions may be performed before forming the word line structure WS (or the word line WL).

Referring to FIG. 6, a buffer layer 30, a lower preliminary conductive layer 410, an intermediate preliminary conductive layer 420, and an upper preliminary conductive layer 430 (collectively referred to as preliminary conductive layers), an insulating capping layer 440, and a plurality of direct contact holes DCH may be formed on/in the formed substrate 10. In this case, a same material as that of a lower preliminary conductive layer 410 among the preliminary conductive layers 410, 420, and 430 may fill the direct contact holes DCH. The direct contact holes DCH may be isolated from each other and may have a planar shape such as a circle, an ellipse, or a rectangle, but the present disclosure is not limited thereto.

Although the buffer layer 30 is illustrated as including two insulating layers, the lower insulating layer 31 and the upper insulating layer 32 in FIG. 6, it is not limited thereto and may include a single layer, a triple layer, or four or more insulating layers.

The lower preliminary conductive layer 410 positioned at a lower portion (e.g., the lowermost portion) among the preliminary conductive layers may include a semiconductor material containing impurities, e.g., polysilicon, and may fill the direct contact holes DCH. However, the embodiment of the present disclosure is not limited thereto. For example, each of the preliminary conductive layers 410, 420, and 430 may include a conductive silicide compound, a conductive metal nitride, a metal, and/or a metal alloy. According to some embodiments of the present disclosure, the lower preliminary conductive layer 410 may include a semiconductor material containing impurities, the intermediate preliminary conductive layer 420 may include, for example, a conductive silicide compound or a conductive metal nitride, and the upper preliminary conductive layer 430 may include, for example, a metal or a metal alloy.

According to some embodiments of the present disclosure, instead of the three preliminary conductive layers 410, 420, and 430, a single preliminary conductive layer, two or four or more preliminary conductive layers may be used.

The insulating capping layer 440 may include, for example, silicon oxide, silicon nitride, silicon oxynitride (SiON), silicon oxycarbonitride (SiOCN), and a combination thereof, but the present disclosure is not limited thereto.

Subsequently, the insulating capping layer 440 and the three preliminary conductive layers 410, 420, and 430 on an area where a connection portion of the word line structure WS is positioned (hereinafter referred to as a “connection area”) may be removed. In this operation, a process for forming a transistor of a core region (not illustrated) may be performed.

Subsequently, an insulating layer 450 may be disposed in the area from which the insulating capping layer 440 and the three preliminary conductive layers 410, 420, and 430 are removed and may be disposed on the insulating capping layer 440. The filling insulating layer 47 may be disposed on the insulating layer 450 in the (removed) area. For example, a surface of the concave connection area (e.g., the area from which the insulating capping layer 440 and the three preliminary conductive layers 410, 420, and 430 are removed) may be filled with the filling insulating layer 47 to planarize the surface (e.g., an upper surface of the filling insulating layer 47 may be coplanar with an upper surface of the insulating layer 450 on the insulating capping layer 440.

The insulating layer 450 may include, for example, silicon oxide, silicon nitride, silicon oxynitride (SiON), silicon oxycarbonitride (SiOCN), and a combination thereof, but the present disclosure is not limited thereto.

The filling insulating layer 47 may include an insulating material having a desired charging characteristic. For example, the filling insulating layer 47 may include a boron-phosphor silicate glass (BPSG) film, a high density plasma (HDP) oxide film, an O₃-TEOS film, an undoped silicate glass (USG), and/or a tonen silazene (TOSZ) material.

Referring to FIG. 7 and FIG. 8, layers on the substrate 10 and the substrate 10 may be etched to form a plurality of word line separation grooves WSH and a plurality of bit line separation grooves BSH.

The filling insulating layer 47, the insulating layer 450, the buffer layer 30, and the substrate 10 may form sidewalls of the word line separation groove WSH, and a lower (e.g., the lowermost) surface thereof may be lower than a lower (e.g., lowermost) surface of the word line structure WS. The word line separation groove WSH may be wider than the word line structure WS (e.g., in the second horizontal direction). The word line separation groove WSH may overlap at least one word line structure WS among a pair of word line structures WS connected to each other to separate one from another. The drawing shows an example in which the word line separation grooves WSH are formed in even-numbered word line structures WS, but conversely, the word line separation grooves WSH may be formed in odd-numbered word line structures WS.

The insulating layer 450, the preliminary conductive layers 410, 420, and 430, the buffer layer 30, and the substrate 10 may form sidewalls of the bit line separation grooves BSH, and a lower (e.g., the lowermost) surface of the bit line separation grooves BSH may be at substantially a same position as that of the word line separation groove WSH in the vertical direction. As illustrated in FIG. 1 and FIG. 2, the bit line separation grooves BSH may be alternately positioned with (e.g., at least a portion of) bit line structure extensions BSE to be formed later.

In the present embodiment, it has been described that the word line separation groove WSH is formed in a same process as that of the bit line separation groove BSH, but the word line separation groove WSH may be formed in a process different from that of the bit line separation groove BSH.

In FIG. 7, the word line separation groove WSH and the bit line separation groove BSH are illustrated as rectangles, but the planar shapes of them are not limited thereto.

Next, referring to FIG. 9, a mask layer 460 may be disposed (e.g., deposited) on the insulating layer 450. In this case, the mask layer 460 may fill the word line separation groove WSH and the bit line separation groove BSH. The mask layer 460 may include, for example, silicon oxide, silicon nitride, silicon oxynitride (SiON), silicon oxycarbonitride (SiOCN), and a combination thereof, but the present disclosure is not limited thereto.

Referring to FIG. 10 and FIG. 11, the mask layer 460, the insulating layer 450, the insulating capping layer 440, and the three preliminary conductive layers 410, 420, and 430 may be etched to form a plurality of bit line structures BS. As illustrated in FIG. 10, end portions of the bit line structures BS may include a widely expanded portion, the bit line extensions BSE, and the bit line extensions BSE may alternately positioned with the bit line separation grooves BSH.

Subsequently, referring to FIG. 12, a bit line spacer 50, a filling spacer 55 (in FIG. 3), a buried contact BC, a partition wall 48, a cell spacer 58 (in FIG. 3), and the like may be formed. In this operation, an upper portion of the bit line structure BS, e.g., the mask layer 46, and the insulating layer 45 thereunder are partially removed, so that a height of the bit line structure BS may not be constant and may be jagged.

Referring to FIG. 13 and FIG. 14, a plurality of word line connection plug holes WLH exposing the word line WL and a plurality of bit line connection plug holes BLH exposing an upper conductive layer 43 of the bit line BL may be formed.

Subsequently, referring to FIG. 15, a first preliminary conductive barrier layer 640 and a second preliminary conductive layer 660 are stacked.

Finally, referring to FIG. 1 to FIG. 3, the first preliminary conductive barrier layer 640 and the second preliminary conductive barrier layer 660 may be etched along with layers therebelow to form a plurality of word line connection plugs WP, a plurality of bit line connection plugs BP, and a plurality of landing pads LP, and removed portions may be filled with the pad separation insulating layer 70.

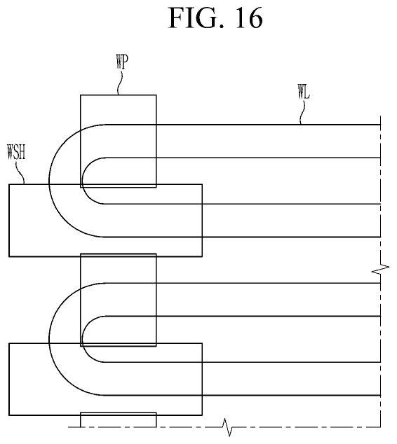

According to the present disclosure, the word line separation groove WSH and the word line connection plug WP may have various arrangements and shapes in addition to those shown in FIG. 1, which will be described in detail with reference to FIG. 16 to FIG. 21.

FIG. 16 to FIG. 18 each illustrate a layout diagram of a word line separation groove and a word line connection plug of a semiconductor device according to some embodiments of the present disclosure.

FIG. 16 illustrates an example in which the word line separation groove WSH and the word line connection plug WP are closer to (e.g., moved toward) an end portion of the word line WL in the first horizontal direction compared to FIG. 1.

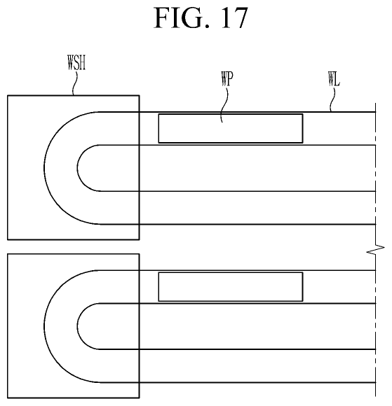

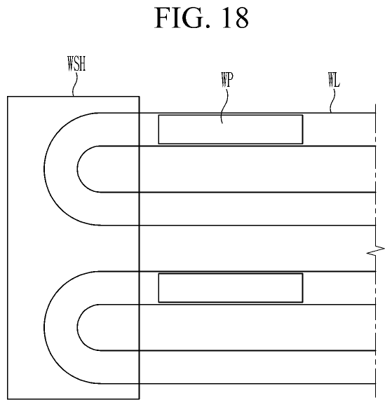

In the embodiment illustrated in FIG. 17 and FIG. 18, the word line separation groove WSH completely overlap (e.g., covers) a connection portion of each pair of word lines WL in the vertical direction, and the word line connection plug WP does not deviate from the word line WL. In the case of FIG. 17, one word line separation groove WSH is allocated to each pair of word lines WL, and in the case of FIG. 18, one word line separation groove WSH extending in the second horizontal direction completely covers connection portions of all word lines WL. In FIG. 17, for example, the word line separation groove WSH may overlap one of the pair of word lines WL in the vertical direction at an area near the end portion of the pair of word lines WL. For example, in FIG. 17, two adjacent word line separation grooves WSH may overlap one of the end portions of the pair of word lines WL. In FIG. 18, for example, the word line separation groove WSH may overlap both word lines WL of the pair of word lines WL in the vertical direction at an area near the end portion of the pair of word lines WL. In FIG. 18, for example, two word line separation grooves WSH may be referred to as being connected to each other.

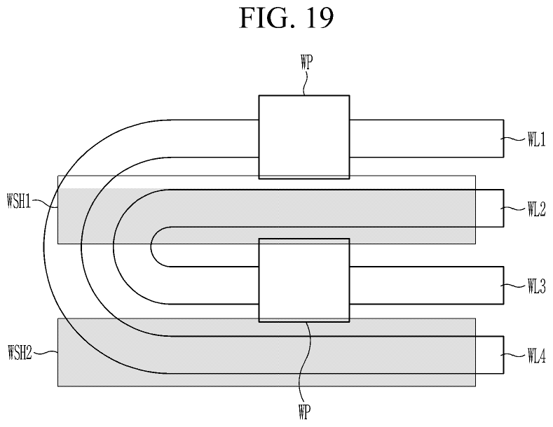

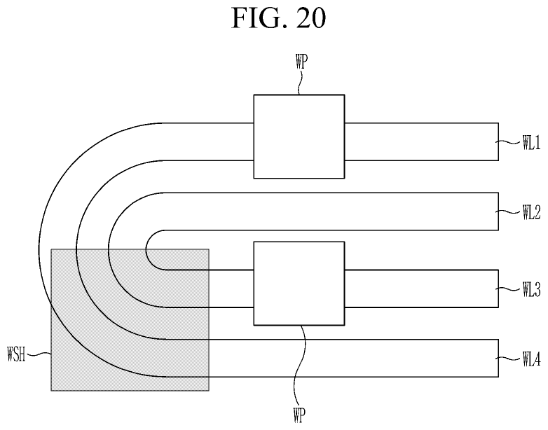

FIG. 19 to FIG. 20 each illustrate a layout diagram of a word line, a word line separation groove, and a word line connection plug of a semiconductor device according to some embodiments of the present disclosure.

In the embodiment illustrated in FIG. 19 and FIG. 20, two adjacent word lines WL2 and WL3 are connected to each other, and two word lines WL1 and WL4 located outside of them, that is, above and below them, are connected to each other. Hereinafter, first, second, third, and fourth word lines WL1, WL2, WL3, and WL4 are referred to in order from the top, and accordingly, it may be said that the second word line WL2 and the third word line WL3 are connected to each other, and the first word line WL1 and the fourth word line WL4 are connected to each other.

In FIG. 19, word line separation grooves WSH1 and WSH2 may be positioned for each of the two word lines WL1 to WL4. Specifically, the word line separation grooves WSH1 and WSH2 may extend along the second and fourth word lines WL2 and WL4 at even-numbered ends, that is, at ends of the second and fourth word lines WL2 and WL4. Alternatively, word line separation grooves may be positioned in odd-numbered, that is, first and third word lines WL1 and WL3. For example, in FIG. 19, the word line separation grooves WSH 1 and WSH2 may be referred to as being adjacent to each other.

In the case of FIG. 20, one word line separation groove WSH may be positioned for each of the four word lines WL1 to WL4, and one word line separation groove WSH may be disposed at ends of the two word lines WL3 and WL4. Although the drawing shows that the word line separation groove WSH is positioned at the ends of the third and fourth word lines WL3 and WL4, it may be positioned at the ends of the first and second word lines WL1 and WL2. For example, in FIG. 20, the word line separation groove WSH may be referred to as having two word line separation grooves WSH connected to each other.

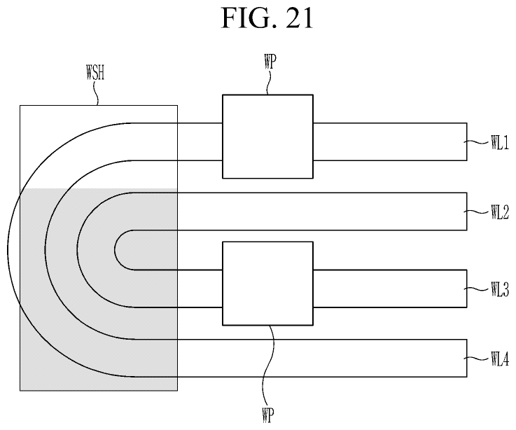

In FIG. 21, one word line separation groove WSH may be positioned for each of the four word lines WL1 to WL4, but unlike in FIG. 20, one word line separation groove WSH may extend in the second horizontal direction and may be positioned at the ends of all four word lines WL1 to WL4. For example, in FIG. 21, the word line separation groove WSH may be referred to as having two word line separation grooves WSH connected to each other.

As described above, according to an embodiment of the present disclosure, a degree of freedom in the shape and arrangement of word line separation grooves and word line connection plugs may be increased to reduce a short circuit between word line connection plugs and disconnection of word lines WL.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A manufacturing method for a semiconductor device, comprising:
forming first and second word lines in a substrate, wherein respective ends of the first and second word lines are connected to each other;
forming a first separation groove between the first word line and the second word line, wherein the first separation groove includes a first insulating layer; and
forming first and second bit lines on the substrate.

2. The manufacturing method of claim 1, wherein the forming of the first and second bit lines comprises:
stacking a conductive layer on the substrate;
forming a second separation groove by primary etching the conductive layer; and
forming the first bit line and the second bit line separated from each other by the second separation groove by secondary etching the conductive layer,
wherein the first separation groove and the second separation groove are formed by a same process,
wherein the second separation groove is at least partially filled with the first insulating layer,
wherein the conductive layer is separated into a first portion and a second portion by the second separation groove, and
wherein the second separation groove extends into the substrate.

3. The manufacturing method of claim 2, further comprising:
removing a portion of the conductive layer that is in a first region where the first separation groove is to be formed before forming the first separation groove; and
forming a second insulating layer in the first region,
wherein the forming of the first and second separation grooves includes etching the second insulating layer.

4. The manufacturing method of claim 3, further comprising:
forming a third insulating layer under the second insulating layer and above the conductive layer,
wherein the forming of the first and second separation grooves includes etching the third insulating layer.

5. The manufacturing method of claim 1, wherein the first separation groove separates the first word line and the second word line, and
wherein the first separation groove overlaps the second word line.

6. The manufacturing method of claim 1, wherein the first separation groove overlap a connection between the first word line and the second word line.

7. The manufacturing method of claim 1, further comprising:
forming third and fourth word lines in the substrate separated from the first and second word lines, and connected to each other at respective ends; and
forming a second separation groove separating the third word line and the fourth word line.

8. The manufacturing method of claim 7, wherein the first separation groove and the second separation groove are connected to each other.

9. The manufacturing method of claim 7, wherein the third word line is at an opposite side of the second word line with respect to the first word line, and the fourth word line is at an opposite side of the first word line with respect to the second word line.

10. The manufacturing method of claim 9, wherein the first separation groove and the second separation groove are connected to each other and are separated from the first and third word lines.

11. The manufacturing method of claim 1, further comprising:
forming third and fourth word lines in the substrate separated from the first and second word lines, and connected to each other at respective ends,
wherein the first separation groove overlaps a connection between the third word line and the fourth word line.

12. The manufacturing method of claim 1, further comprising:
forming third and fourth word lines in the substrate separated from the first and second word lines, and connected to each other at respective ends; and
forming a third separation groove separated from the first separation groove and overlapping a connection between the third word line and the fourth word line.

13. The manufacturing method of claim 1, further comprising:
forming a first connection plug connected to the first word line and a second connection plug connect to the first bit line.

14. The manufacturing method of claim 13, wherein the first connection plug has a wider width than that of the first word line in a horizontal direction.

15. The manufacturing method of claim 14, wherein the first connection plug partially overlaps the first separation groove.

16. A manufacturing method for a semiconductor device, comprising:
forming first and second word lines in a substrate, wherein respective ends of the first and second word lines are electrically connected to each other;
forming a first separation groove, wherein the first word line and the second word line are electrically separated by the first separation groove and the first separation groove is at least filled by a first insulating layer; and
forming first and second bit lines on the substrate.

17. The manufacturing method of claim 16, further comprising:
forming third and fourth word lines in the substrate separated from the first and second word lines, and electrically connected to each other at respective ends; and
forming a second separation groove that electrically separates the third word line and the fourth word line.

18. The manufacturing method of claim 17, wherein the first separation groove and the second separation groove are adjacent to each other.

19. A manufacturing method for a semiconductor device, comprising:
forming first and second word lines in a substrate, wherein respective ends of the first and second word lines are electrically connected to each other;
forming a first separation groove between the first word line and the second word line, wherein the first separation groove is at least filled by a first insulating layer;
forming first and second bit lines on the substrate;
forming third and fourth word lines in the substrate separated from the first and second word lines, and electrically connected to each other at respective ends; and
forming a second separation groove between the third word line and the fourth word line.

20. The manufacturing method of claim 19, wherein the first separation groove and the second separation groove are adjacent to each other and are separated from the first and third word lines.
